(19) United States
(12) Patent Application Publication
(10) Pub. No.: US 2007/0166903 A1
(43) Pub. Date: Jul. 19, 2007

(54) Semiconductor structures formed by stepperless manufacturing

(76) Inventor: Bohumil Lojek, Colorado Springs, CO (US)

Correspondence Address: SCHNECK & SCHNECK, P.O. BOX 2-E, SAN JOSE, CA, 95109-0005, US

(21) Appl. No.: 11/333,117

(22) Filed: Jan. 17, 2006

(51) Int. Cl. H01L 21/8234; H01L 21/336; H01L 21/3205

(52) U.S. Cl. 438/197; 438/305; 438/286; 438/257; 438/593

(57) ABSTRACT

A manufacturing method for an array of polysilicon fins built up into fin blocks that are aligned in a comb-like array occupying a wafer surface. By subsurface and supersurface contact, fin blocks can be arranged into components or even systems. The method involves wafer area masking and etching over the wafer surface without step-and-repeat lithography. In an exemplary embodiment, an EEPROM memory array has memory cells that combine a floating gate transistor and a select transistor into a single cell. The floating gate has a tunnel oxide window distal to the wafer substrate and facing an erase electrode while a capping control gate electrode has a portion next to the floating gate. The control gate and the floating gate have portions between source and drain electrodes for communicating with the channel therebetween. The control gate and the erase gate have supersurface contacts to memory array word lines while the subsurface source and drain electrodes are extended to memory array bit lines.

### TECHNICAL FIELD

The invention relates to integrated circuit manufacturing and, in particular to MOS transistor and nonvolatile memory structure manufacturing.

### BACKGROUND OF THE INVENTION

There are known techniques for construction of devices with features smaller than the limits of optical resolution. A first technique is to use the edges of lines that are optically resolved to define small gaps less than the limits of optical resolution to allow building of features, for example, by diffusion and growth in a gap, or by implantation. A second technique is to build large features, then etch the features to a sliver or spacer. The sliver can act as a mask allowing construction of devices on sides of the sliver or the sliver may be a building material itself. An upright freestanding sliver is sometimes called a fin or spacer. Various types of semiconductor structures can use silicon fins, such as MOS transistors known as surrounding gate transistors or finfets. A potential application is in forming a transistor memory.

Non-volatile memory cells usually employ floating gate MOS transistors. The charged and uncharged states of the floating gate represent digital states of zero and one. Two common types of memory array employing floating gate transistors are EEPROM arrays and flash arrays. In an EEPROM array each transistor can be selected for a program, erase and read operation, while in a flash array, individual transistors are not selected, particularly for erase operations, but blocks of transistors are erased at one time. An EEPROM transistor memory array requires use of a select transistor for each floating gate device, with the two transistors forming a memory cell. Select transistors, and hence memory cells, are accessed in groups by means of a first common line configured as a word line and a second common line configured as a bit line. The word and bit lines are orthogonal in a circuit diagram, if not in reality, allowing X-Y selection of a memory cell in an X-Y array of cells.

As transistor dimensions become smaller, it becomes more difficult to scale devices downwardly and to provide appropriate voltages to floating gate transistors for selection, read, write and erase. The typical array is a planar structure fabricated on a silicon chip with vertical tunnels called vias making contact with lower chip levels where appropriate voltages are needed. Since present day dimensions for transistors are at the limits of photolithography, it becomes difficult to pattern vias. The precision registration required between overlying masks or layers of a chip is a difficult task in manufacturing EEPROMs of the smallest size since the characteristic sizes of desired features is smaller than characteristic sizes of the vias. In other words, desired features, such as gates, would have to be made larger to accommodate vias and so devices are not scaleable to smaller dimensions.

One of the complicating factors in chip manufacturing is the need to repeat photolithographic patterns over the surface of a wafer for each chip to be manufactured. A special tool known as a step-and-repeat camera, sometimes called a “stepper”, is used to pattern a wafer with the many layers of mask patterns, repeated for each device to be made on a wafer. As devices become smaller, alignment problems arise from layer to layer, with stepper tools having a very high level of sophistication and expense to achieve desired tolerances.

An object of the invention is to devise a semiconductor manufacturing technique that uses structures not defined by a stepper for fabricating wafer scale semiconductor circuits. By “wafer scale manufacturing or fabrication” is meant that stepperless construction is used wherein photomasks can be employed over the entirety of a wafer. In the prior art, contact photomasks are an example of such stepperless construction. However, wafer scale masks have not been used in manufacturing fin structures. Wafer scale manufacturing is to be distinguished from “wafer scale integration” wherein a large number of already manufactured chips on a single wafer are interconnected without the chips being separated and mounted in different packages. Wafer scale interconnection of chips occurs after chips are fabricated but interconnections at different levels are essential. Wafer scale manufacturing can employ wafer scale integration after chips are fabricated.

Accordingly, another object of the invention is to use silicon fin structures as building blocks for wafer scale device manufacturing.

Yet another object of the invention is to devise an exemplary circuit of a type that is suitable for scaleable wafer scale manufacturing, particularly a non-volatile memory array.

### SUMMARY OF INVENTION

The present invention is a new method of integrated circuit construction using silicon fins, built up as bars, aligned in rows that are constructed on a wafer scale basis without steppers. The invention further involves an exemplary non-volatile memory using the technique. The spacing between the rows of bars, as well as the height of the fins within the bars and thickness of the fins is scaleable, almost down to the vanishing point. For example, rows and columns of bars with appropriate gates superimposed on or under a fin may be a memory array so long as needed electrical contacts and interconnections can be made with the top, bottom, or sides of the bars since vias are not used in accordance with the invention. An exemplary EEPROM memory array is disclosed to be a structure where each bar would be an EEPROM memory cell in an X-Y memory array. Each bar would have a height of less than 1000 angstroms, with a length and width of about 3000 angstroms. Similar X-Y arrays of logic gates could be built so that any structure that is a combination of logic gates could be fabricated. Fabrication of processors could be carried out using this technique so long as the processor design is specified in terms of logic gates. Since many millions of bars could be fabricated on a wafer, the dimensions of a complicated device, such as a processor becomes much smaller, power requirements are smaller and speed limitations arising from interconnect distances are reduced since everything is more compact.

To build on a wafer scale basis without stepping, wafer size contact masks are used to make linear patterns. A series of such linear patterns allows construction of various types of MOS transistors, without isolation structures, such as LOCOS or STI. In the case of an EEPROM memory array, each memory cell consists of a floating gate transistor and a select transistor. Both transistors are made within the same bar forming a single cell in an X-Y array. Both transistors occupy the space of a single device by sharing a single source and drain.

The combined floating gate and select transistor devices are built starting with an X-Y array of polysilicon fins on a semiconductor wafer with the fins being aligned in an ultra compact comb-like structure. The fins, being insulated from the substrate, are to be used as the floating gates of MOS EEPROM transistors. Tunnel oxide is built on the top side of the floating gate distal to the substrate and a gate formed from a second polysilicon layer (“poly two”) that functions as an erase gate word line is built over the tunnel oxide. Capping the poly two gate is a third polysilicon layer (“poly three”) gate that wraps around both the erase gate and the floating gate and functions as a control gate word line. Subsurface source and drain electrodes are built at sides of the floating gate and a downward extension of the control gate so that the gates can sense electrical conduction in the channel between source and drain electrodes, as well as by setting the threshold for conduction in the usual way for a non-volatile memory device. At least one of the subsurface source and drain serves as a subsurface bit line that can communicate with devices throughout the array. The floating gate and control gate are word lines that can do likewise but in an orthogonal direction in an X-Y array. In this manner both a floating gate device and a select transistor are fabricated on a single fin, forming a fin block which, when aligned presents a comb-like appearance of an array of similar devices.

### BRIEF DESCRIPTION OF DRAWINGS

FIGS. 1, 3, 5, 7, 9, and 11 are sequential side sectional view of layers in a fin block manufacturing process in accordance with the present invention.

FIGS. 2, 4, 6, 8, 10, and 12 are top views corresponding to FIGS. 1, 3, 5, 7, 9, and 11 respectively.

FIGS. 13, 16, 19, 22, 25, 28, 31, 34, 37, 40, 43, 46, 47, 50, 51, 54, 55, 59, 62, 65, 68, 71, 74, 77, and 80 are sequential side sectional views of layers in a fin block manufacturing process following the process of FIGS. 1-12.

FIGS. 14, 17, 20, 23, 26, 29, 32, 35, 38, and 41 are top views corresponding to FIGS. 13, 16, 19, 22, 25, 28, 31, 34, 37, and 40, respectively.

FIGS. 15, 18, 21, 24, 27, 30, 33, 36, 39, and 42 are orthogonal side sectional views corresponding to FIGS. 13, 16, 19, 22, 25, 28, 31, 34, 37, and 40 respectively.

FIG. 45 is a top view corresponding to the side view of FIG. 44.

FIG. 46 is an orthogonal side sectional view corresponding to FIG. 43.

FIG. 48 is a top view corresponding to FIG. 47.

FIG. 49 is an orthogonal side sectional view corresponding to FIG. 47.

FIG. 52 is a top view corresponding to FIG. 51.

FIG. 53 is an orthogonal side sectional view corresponding to FIG. 51.

FIG. 56 is a top view corresponding to FIG. 55.

FIG. 57 is an orthogonal side sectional view corresponding to FIG. 55.

FIG. 58 is a sequential side sectional view of a fin block manufacturing process following the process step shown in FIG. 55.

FIGS. 60, 63, 66, 69, 72, 75, 78, and 81 are top views corresponding to FIGS. 59, 62, 65, 68, 71, 74, 77, and 80 respectively.

FIGS. 61, 64, 67, 70, 73, 76, 79, and 85 are orthogonal side sectional views corresponding to FIGS. 59, 62, 65, 68, 71, 74, 77, and 80 respectively.

FIG. 83 is a top view of an end of a fin block shown in FIG. 82.

FIG. 84 is a side plan view of an electrical structural device representing the physical structure of FIG. 82.

FIG. 85 is an electrical diagrammatic representation of the memory cell of FIG. 84.

FIG. 86 is an electrical schematic of an EEPROM memory X-Y array showing memory cells as shown in FIG. 85 with read voltages applied.

FIG. 87 is an electrical schematic of an EEPROM memory array as shown in FIG. 86 with program voltages applied.

FIG. 88 is an electrical schematic of an EEPROM memory array as shown in FIG. 86 with erase voltages applied.

### BEST MODE OF CARRYING OUT THE INVENTION

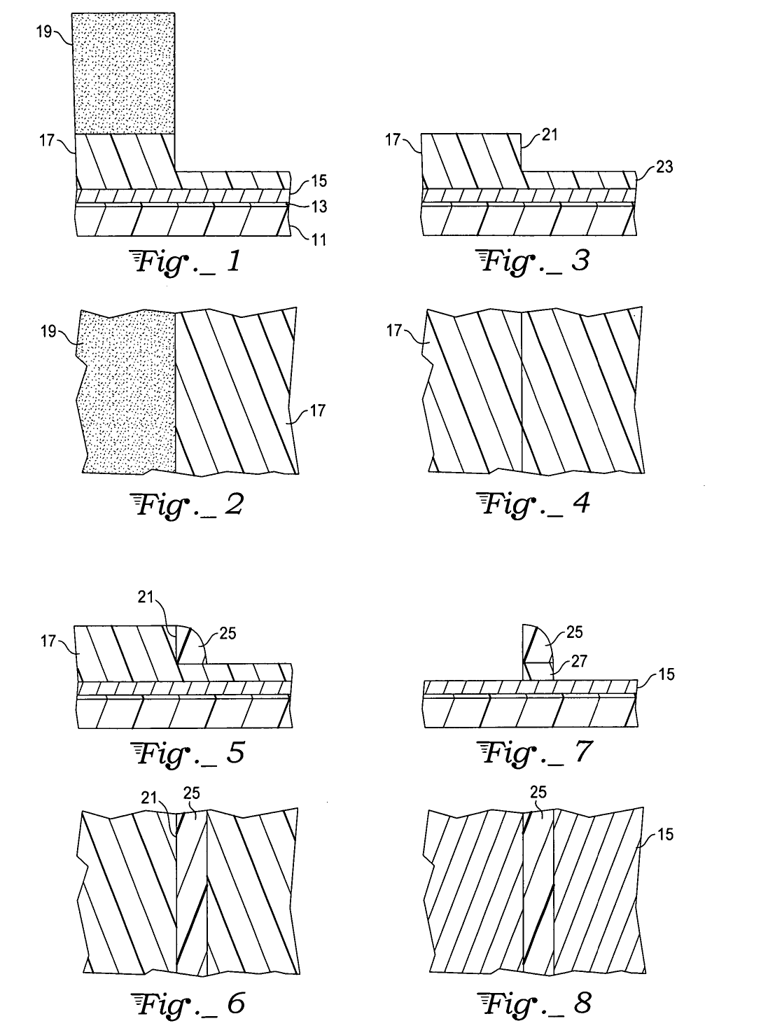

With reference to FIGS. 1 and 2, a substrate 11 is typically a doped semiconductor wafer, typically a P type wafer. The wafer has a thin insulative coating, in this case a 100 angstrom or less thick oxide layer 13. Atop the the oxide layer is a first conductive polysilicon layer 15 that is also approximately 500-800 angstroms thick. Atop the polysilicon layer is an insulative vapor deposited layer of TEOS 17 approximately 1500-2000 angstroms thick on the left side of FIG. 1 prior to etching. Atop the TEOS layer is a photo mask 19 seen on the left side of FIGS. 1 and 2, also before etching, with the right side of FIGS. 1 and 2 showing a step 21 created by dry etching. After the dry etch, the mask is removed, as seen in FIGS. 3 and 4. In FIG. 3 the etch is seen to produce a step height of TEOS material that is approximately 1000 angstroms thick. The base 23 of the TEOS step is about 500 angstroms in height and step 21 is approximately 1000 angstroms.

Each layer is applied across the surface of the wafer, with the objective of making a large number of silicon fins aligned in rows and columns. The drawings show a construction of a single fin but masks that are used in making a fin are single masks over the surface of a wafer and not produced by step-and-repeat cameras. An example of such masks are contact masks spanning the entire surface of a wafer.

The manufacturing process results in production of a comb-like structure with each row of the comb being a plurality of aligned fin blocks. Each fin block is built from a silicon fin as a starting material. The following embodiment describes construction of an EEPROM memory in an X-Y array of memory cells, but other structures such as an array of logic gates could be built. It is important to note that the construction is entirely bottom to top layering with no vias connecting top layers to underlayers and all construction being on a wafer scale basis, without step and repeat construction. Also note that spacers, rather than lines, are used to define certain dimensions, allowing for complete scaleability. No subsurface isolation structures are used between devices.

With reference to FIGS. 5 and 6, a nitride spacer 25 has been built abutting the step 21. The width of the spacer is important for determining the width of a silicon fin to be established beneath the spacer, the nitride spacers built by depositing a layer of nitride over the structure seen in FIG. 3, then etching the nitride except at the corner of the TEOS layer 17, leaving the nitride spacer. Performing a dry etch on the TEOS layer 17 leaves the structure seen in FIGS. 7 and 8. The nitride spacer 25 is seen to reside atop the protected TEOS member 27 which resides on the exposed first polysilicon layer 15. The height of the polysilicon spacer 25 is approximately 1000 angstroms, while the height of the TEOS member 27 is approximately 500 angstroms as previously seen.

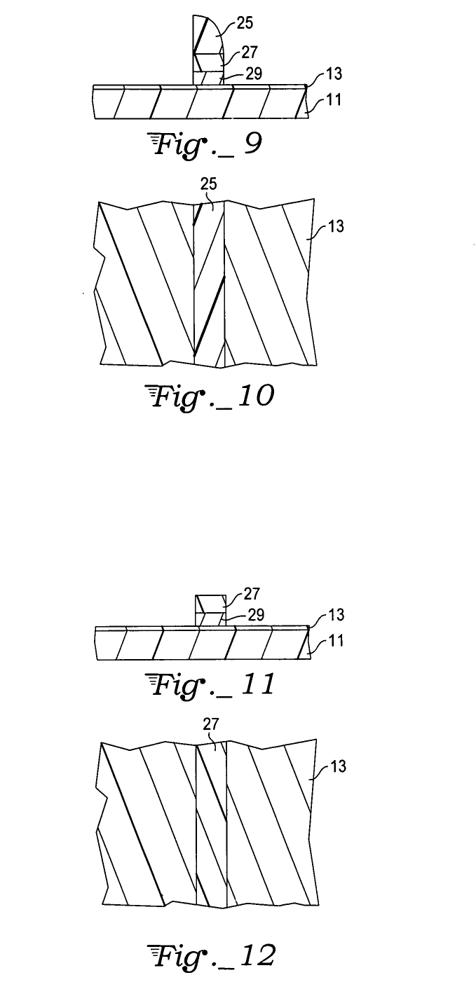

With reference to FIGS. 9 and 10 the first polysilicon layer is dry etched leaving only the polysilicon fin 29 which was protected by TEOS member 27 and the nitride spacer 25. The polysilicon fin 29 is seen to reside atop the oxide layer 13. Now the nitride spacer 25 is etched with a nitride etchant leaving the polysilicon fin 29 covered by the TEOS member 27 as seen in FIGS. 11 and 12. The overall height of the to the TEOS member 27 and the polysilicon fin 29 is approximately 1000 angstroms.

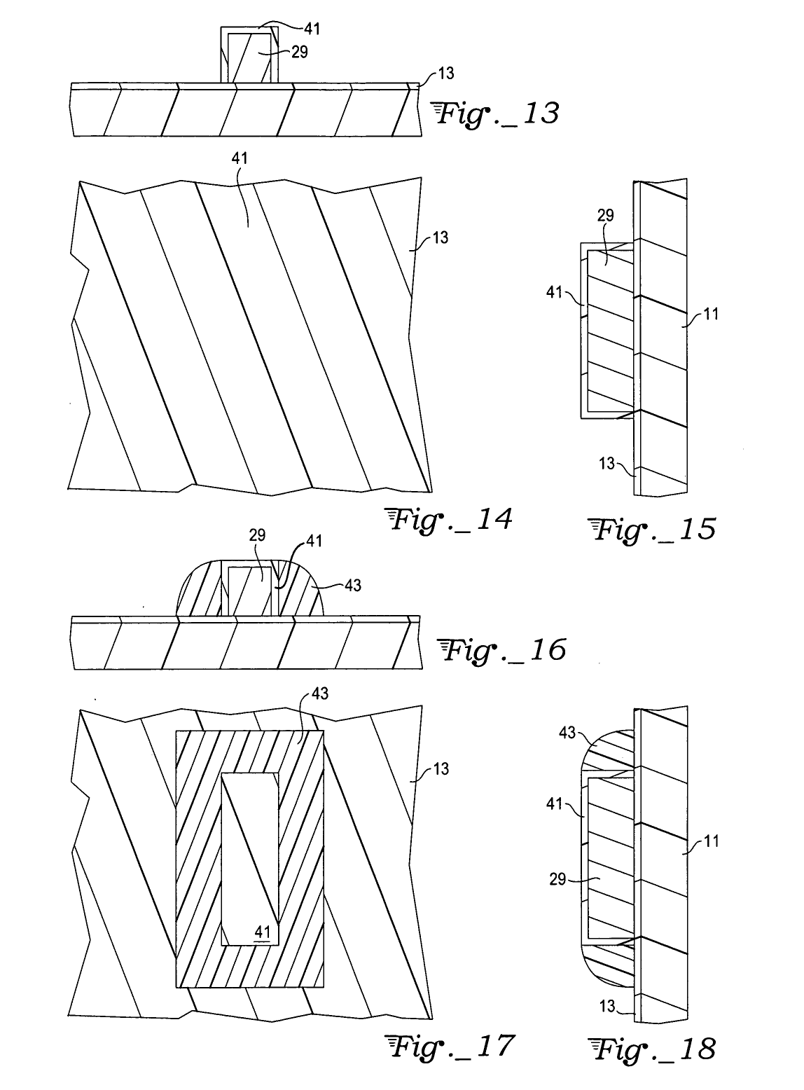

In the present invention, in order to form a floating gate, the TEOS member 27 is removed. The polysilicon fin 29 remains. The polysilicon fin 29 is then oxidized, with a thermal oxide 41 having a thickness of between 50 and 200 angstroms, as seen in FIGS. 13-15. While the polysilicon fin 29 is seen to have an approximately rectangular cross-section ranging in size from between 300-500 angstroms, the linear dimension seen in FIG. 15 is larger, a few thousand angstroms in length, with the oxide completely surrounding the polysilicon fin 29. Although the silicon fin is sometimes called a sliver, the basic shape is a bar shape of rectangular cross section. The cross section need not be rectangular but this is a convenient shape.

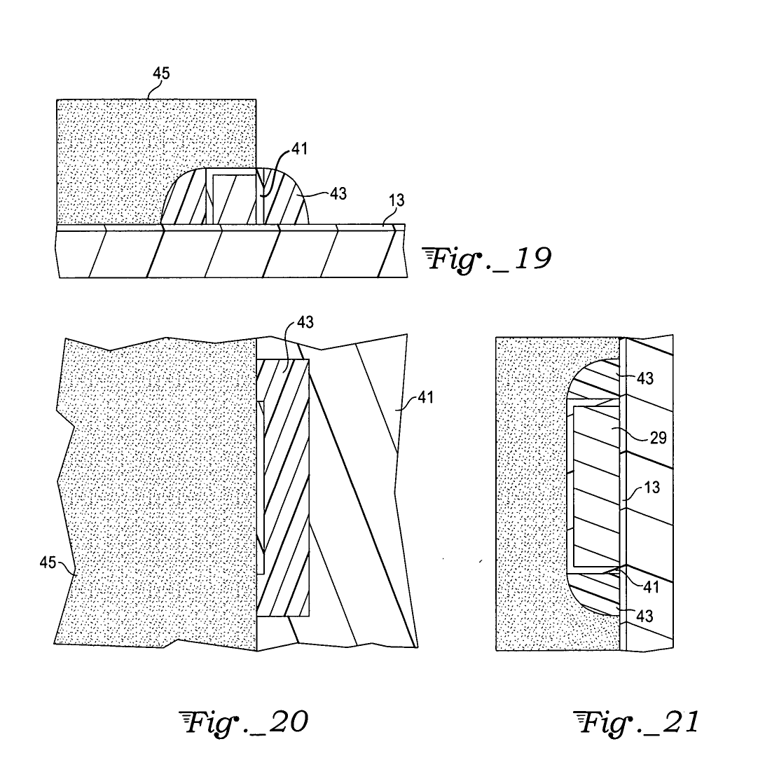

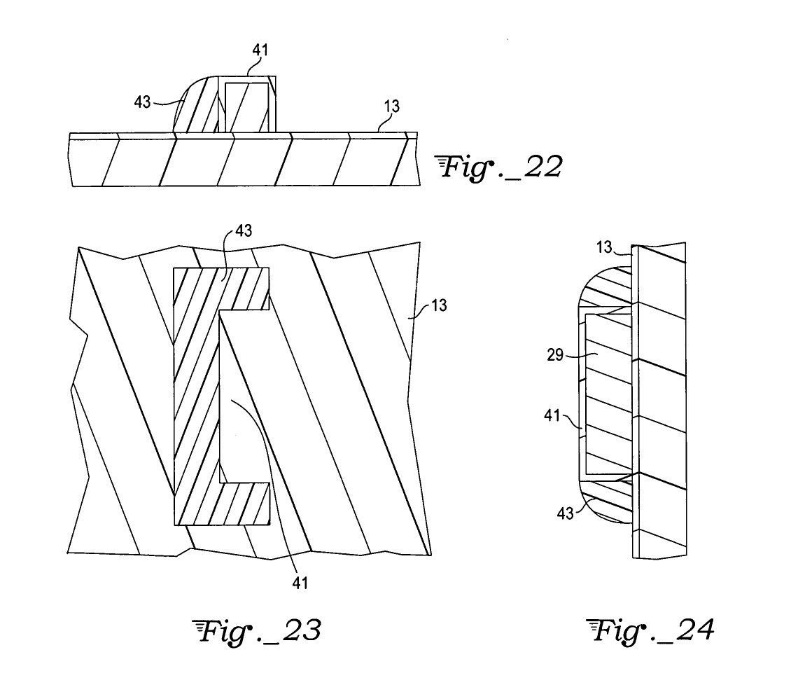

In FIGS. 16-18 a nitride layer is deposited, then partially etched away to define a spacer 43 that completely surrounds the sides of the polysilicon fin 29. The width of the spacer is approximately equal to the width of the fin. The selected height of the polysilicon fin 29 is the main factor determining the width of the nitride spacer 43, a remnant from nitride layer etching. In FIGS. 19-21 a mask 45 covers three of four quadrants of spacer 43. In FIG. 20, if the four quadrants are referred to as north, west, south and east, then north, west and south spacer quadrants are seen to be covered by the mask 45 while the east spacer quadrant is not covered by the mask. This allows etching of the east spacer quadrant so that only the north, west and south spacer quadrants remain. Then the mask 45 is removed as seen in FIGS. 22-24. The unprotected east spacer quadrant has been etched away.

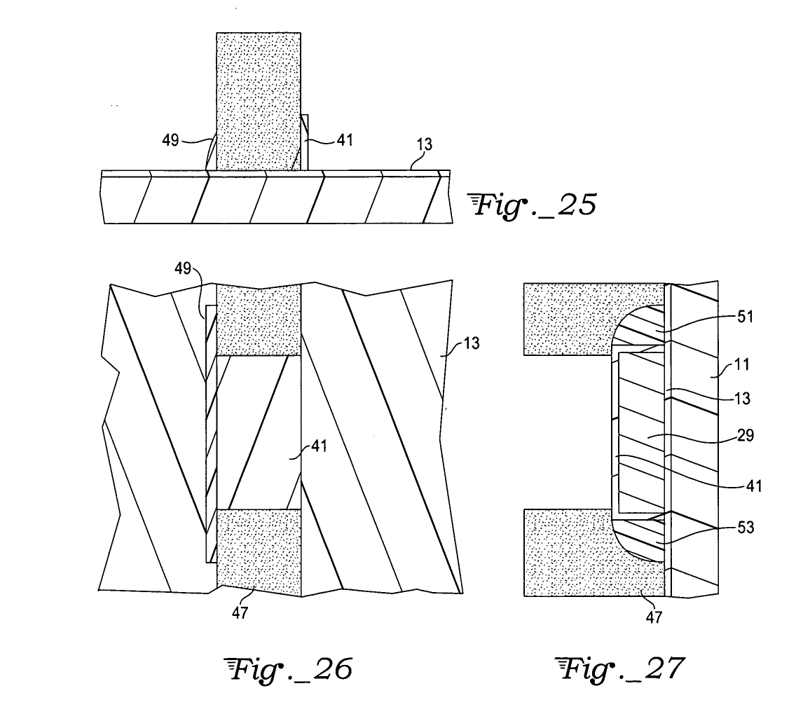

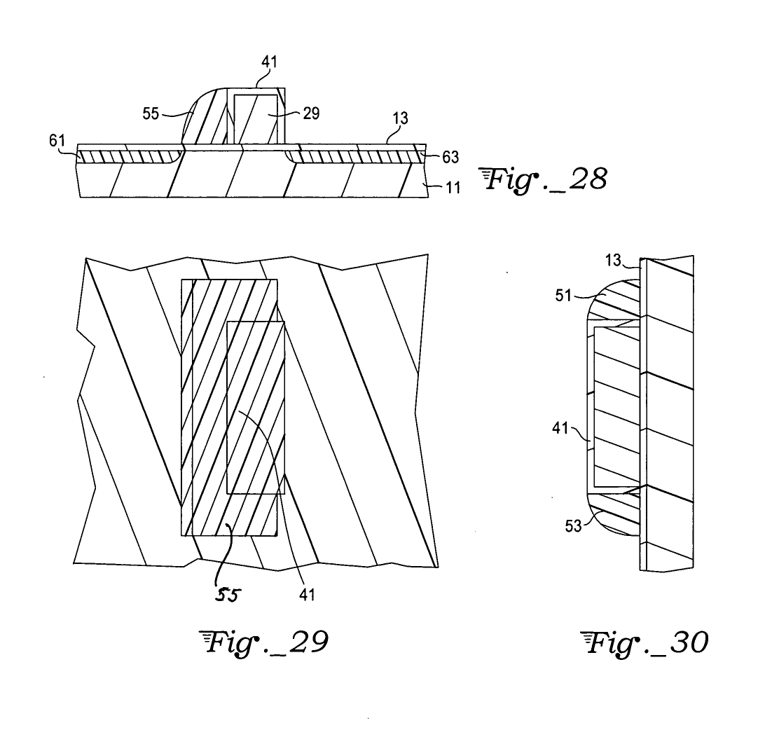

In order to trim the west spacer quadrant and form separation between devices, mask 47 is applied over a portion of the space between fin blocks as seen in FIGS. 25-27. The west spacer quadrant is used to define the location of a subsurface implant and so the western most edge of exposed spacer region 49 is removed by etching. The north and south spacer quadrants 51 and 53, seen in FIG. 27, remain on opposite sides of the polysilicon fin 29 and have no implants. Then the mask 47 is removed and implants are carried out as shown in FIGS. 28-30 where source 61 and drain 63 are implanted into substrate 11. Assuming that the wafer substrate 11 is P-type silicon material, the source and drain implants are N+ material. The source 61 is seen to be spaced from the polysilicon fin by the west spacer quadrant 55 with a total dimension of the spacer quadrant base and the fin being about 600 angstroms in this embodiment. The drain 63 is self aligned by the east edge of fin block 29. Both the source 61 and the drain 63 will become buried bit lines with the respective implants extending linearly from one fin block to the next without interruption. Thus, while the fin blocks are interrupted with small gaps between aligned blocks, the bit lines continue for the length of the array.

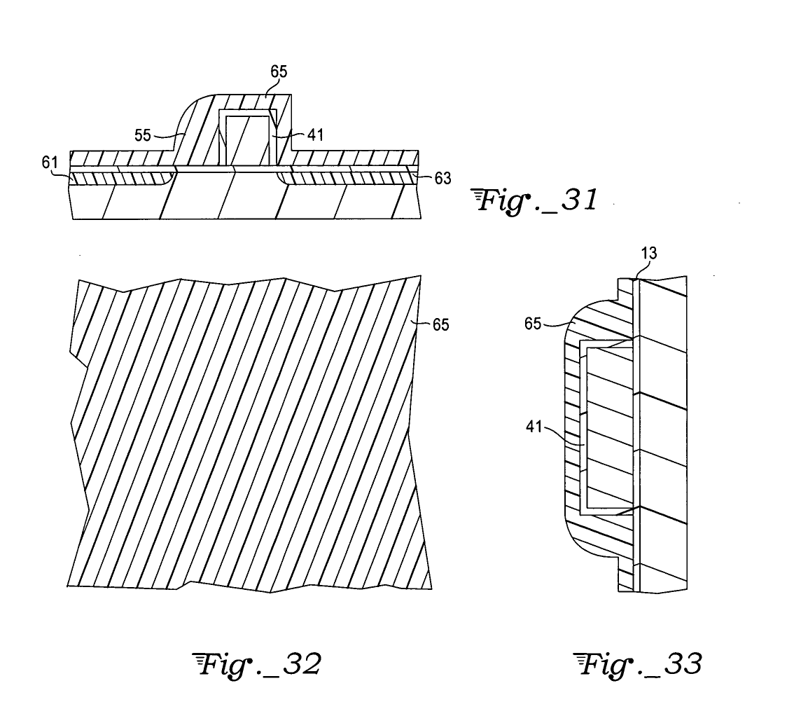

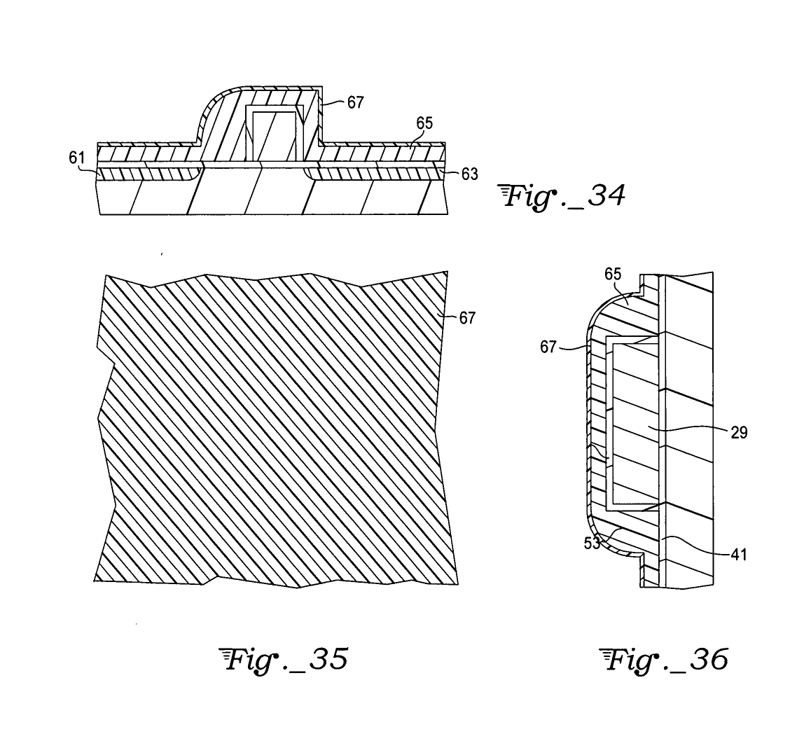

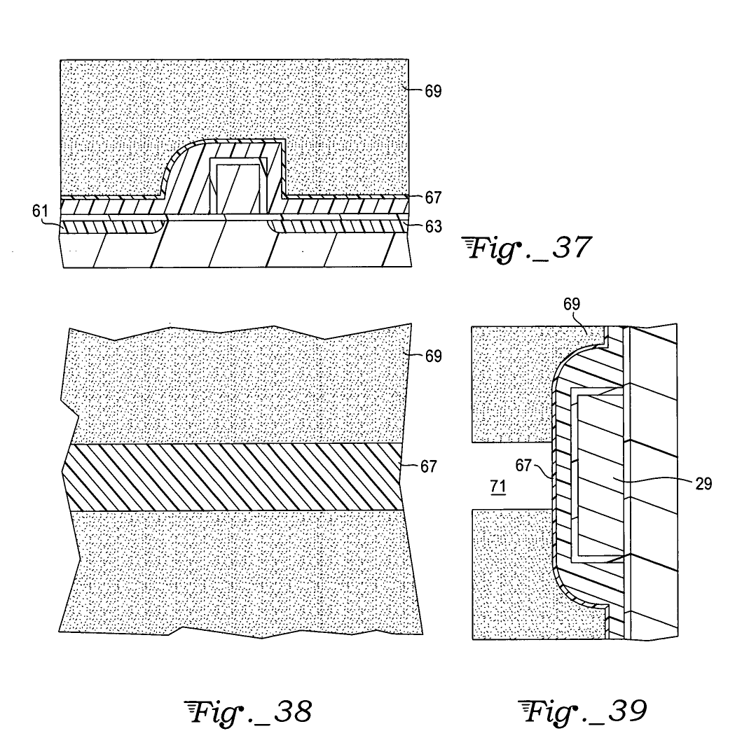

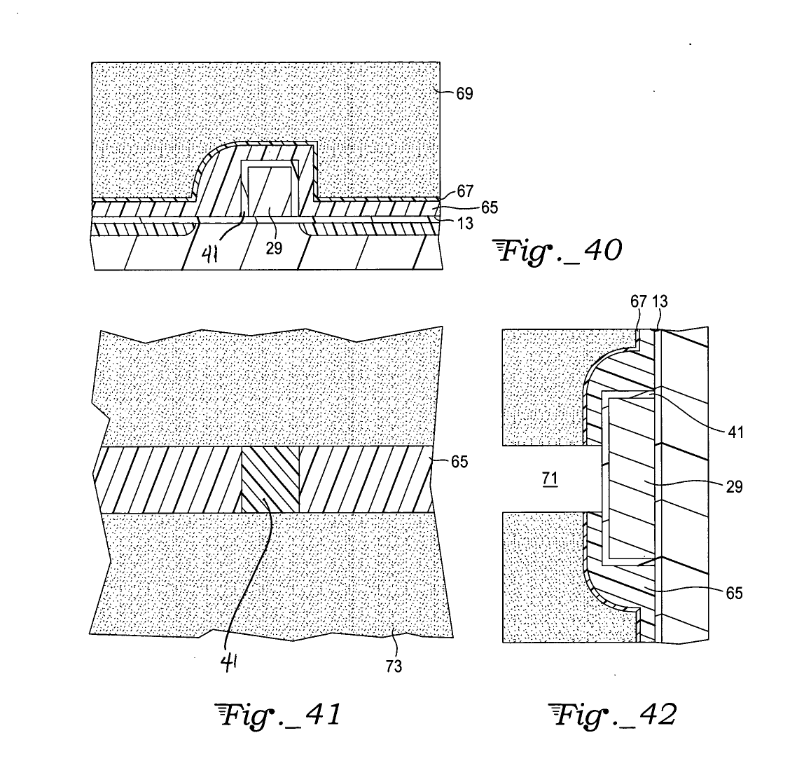

FIGS. 31-33 illustrate deposition of a nitride layer 65 that completely covers the surface of the wafer so that a nitride layer covers the oxide layer 41, as well as oxide layer 13. The thickness of the nitride layer is not important. In FIGS. 34-36 a thermal oxide layer 67 is deposited over the nitride layer. In FIGS. 37-49 a photomask 69 is deposited over the oxide layer 67 and a transverse cut 71 is made by etching across the fin block in the east-west direction. The width of the cut is larger than the width of the tunnel window to be formed later. Referring to FIGS. 40-42, a rectangular opening 73, seen in FIG. 41, reaches the level of thermal oxide 41 as seen in FIG. 42. Thermal oxide is removed on the east and west sides of the opening seen in FIG. 41 so that nitride exists on east and west sides of the opening. In FIG. 42, nitride is seen on north and south sides of the opening. Nitride surrounds opening 71 in all quadrants.

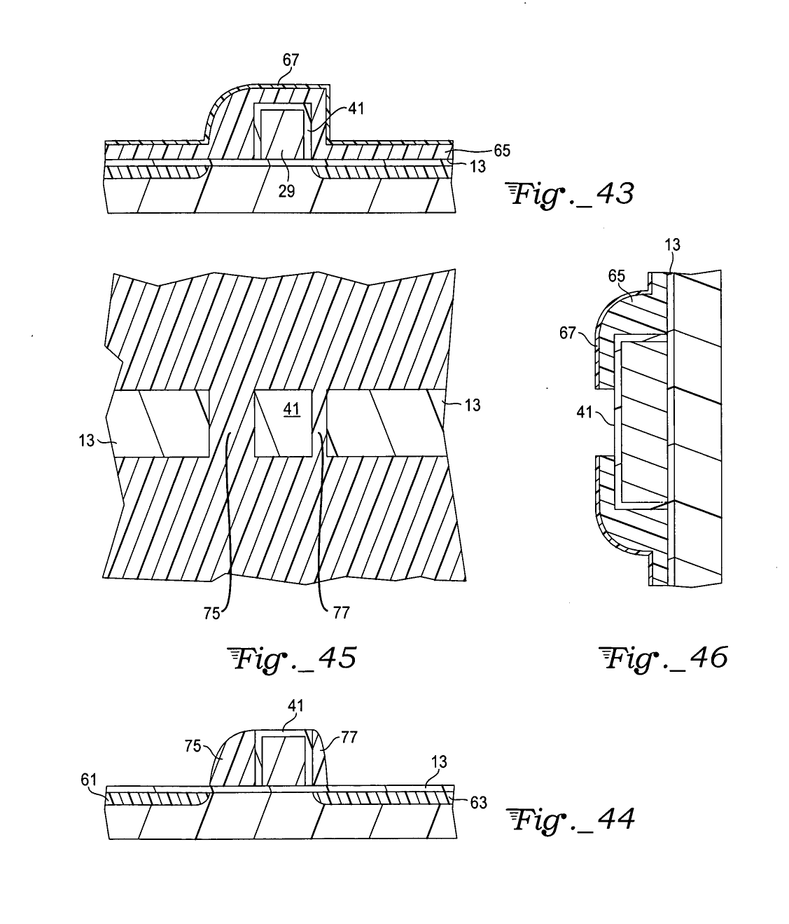

With reference to FIGS. 43-46, the photomask 69, seen in FIG. 40, is shown to have been removed. In FIGS. 44 and 45, the portion of oxide layer over the west spacer 75 and east spacer 77 is seen to be removed, revealing thermal oxide 41. Nitride is also removed in a strip to the west and east of polysilicon fin block 29, revealing a strip of oxide 13 to the west and east of nitride spacers 75 and 77.

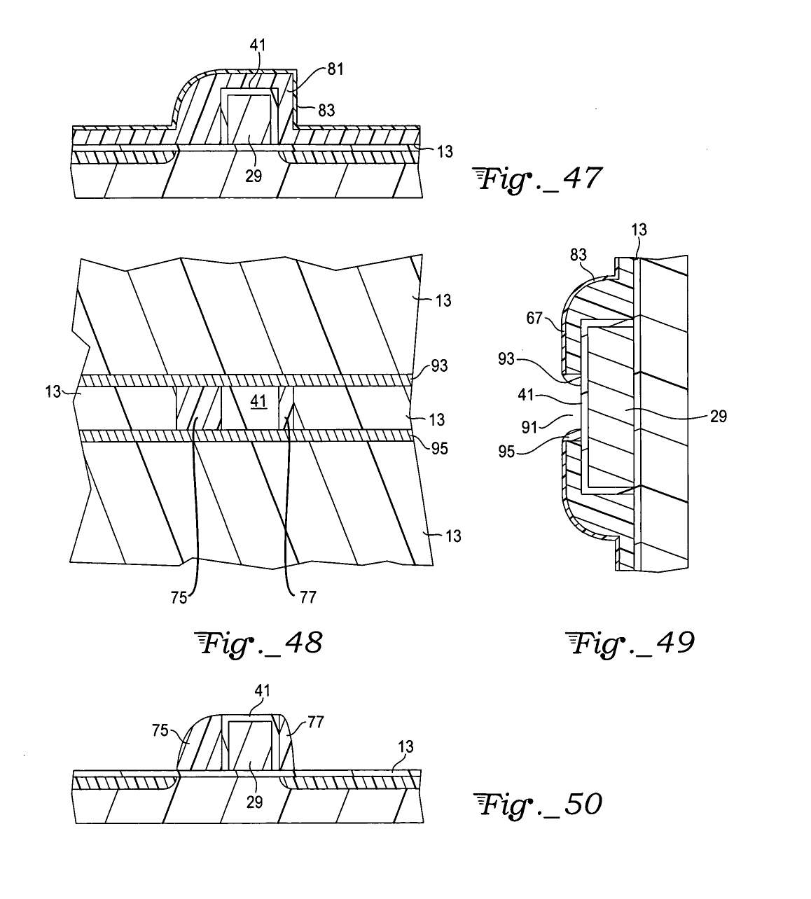

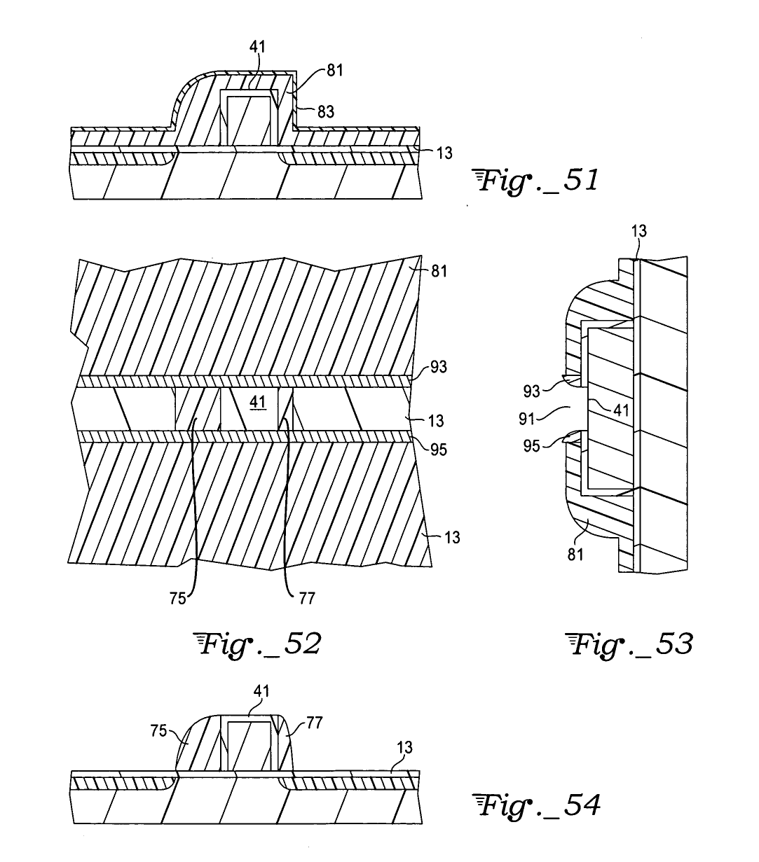

With reference to FIG. 47 a layer of nitride 81 is deposited over the structure of FIG. 44, including the spacers, and then a layer of thermal oxide 83 is grown over the nitride. Now the nitride is etched to establish a tunnel window region 91, seen in FIG. 49, to the level of thermal oxide 41. Window spacers 93 and 95, seen in both FIGS. 48 and 49, are built by re-depositing nitride and then removing the nitride except for the spacers 93 and 95 defining a narrowed tunnel window in window region 91. Oxide at the bottom of the window region is thinned to a mere 10 to 40 angstroms to establish tunnel oxide. Nitride can now be mostly removed except for reestablishing west and east spacers 75 and 77, seen in FIGS. 48 and 50. Note that the tunnel oxide is not contacting the substrate, but is on a side of polysilicon fin 29 distal to the substrate.

After removing oxide layer 83, the nitride layer 81 is only partly etched in the area of the window to be opened. This establishes the window area 91, seen in FIG. 53, with window spacers 93 and 95, seen in both FIGS. 52 and 53, established from redepositied nitride. Now the nitride is re-etched to establish the narrowed tunnel window 91. The oxide layer 41 is thinned, defining the tunnel oxide in window region 91 at a mere 10 to 40 angstroms. Now the remaining nitride can be mostly removed except for spacers 75 and 77, as seen in FIG. 54. A difference in the etching pattern relative to FIGS. 47-50 is that nitride layer 81 is at first left in place when oxide 83 is removed, as seen in FIG. 52, opening window region 91, seen in FIG. 53. Nitride spacers 93 and 95 are built by redepositing nitride, opening window region 91 for thinning of the oxide layer 41, and so on, as explained above.

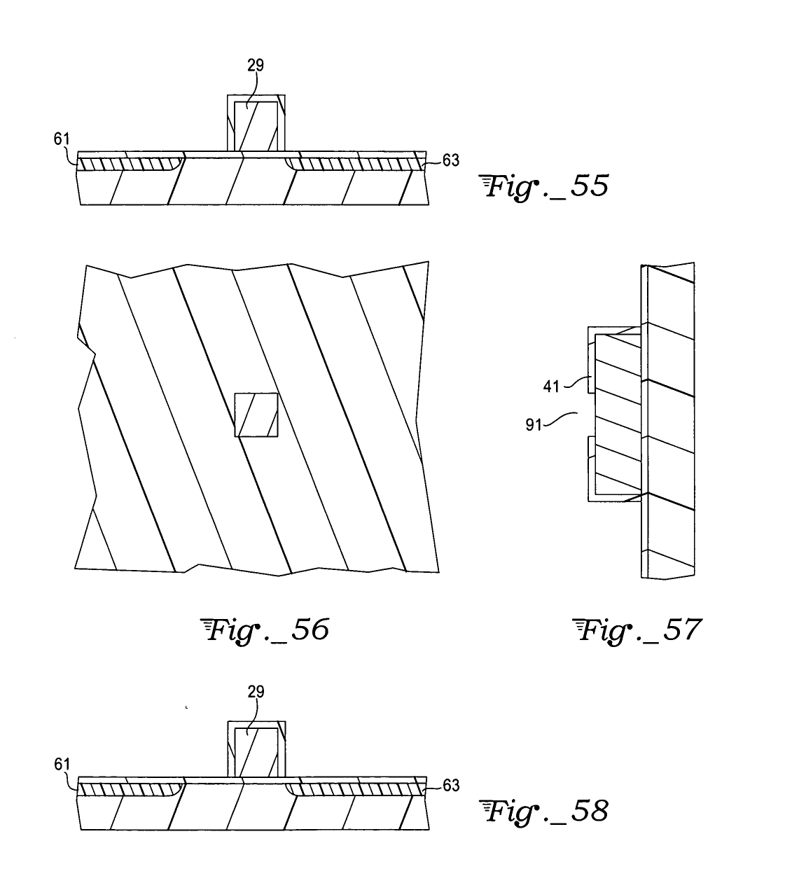

In FIGS. 55-57 all nitride is seen to be removed. In FIG. 55, source 61 is seen to be spaced from polysilicon fin 29 by an amount determined by the spacing of the previously existing spacer from fin block 29. In FIG. 57 the oxide layer is seen to be thin in tunnel window region 91, as thin as approximately 20 to 50 angstroms. The top view of FIG. 56 indicates that only oxide is seen from the top. FIG. 58 indicates a re-oxidation step to fill any small holes or to smooth any oxide irregularities. However, the side profile of the fin block 29 including subsurface electrodes 61 and 63 is the same as FIG. 55.

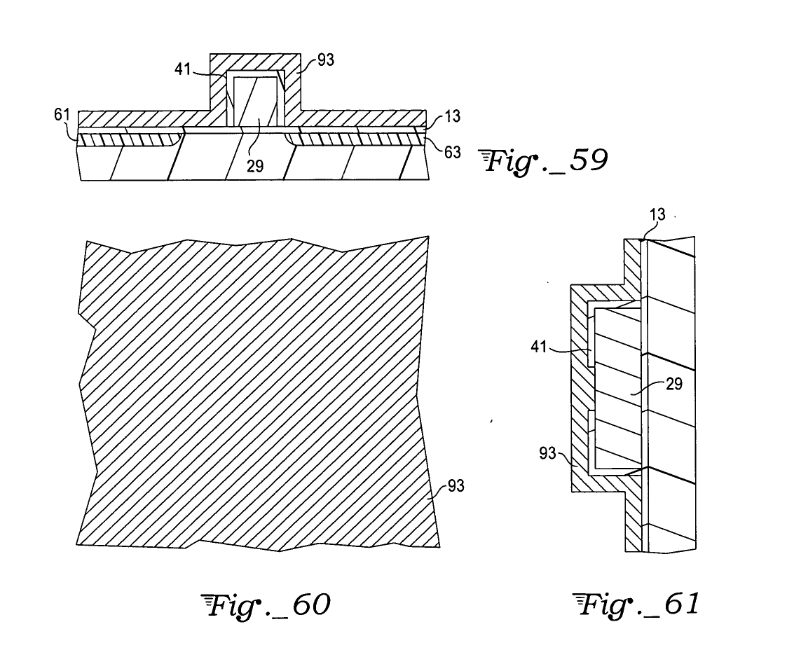

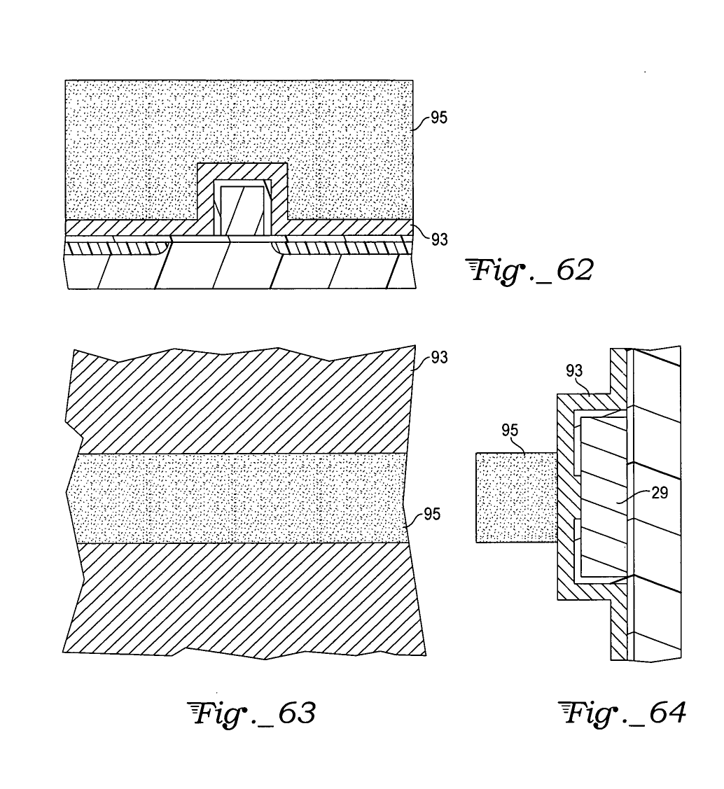

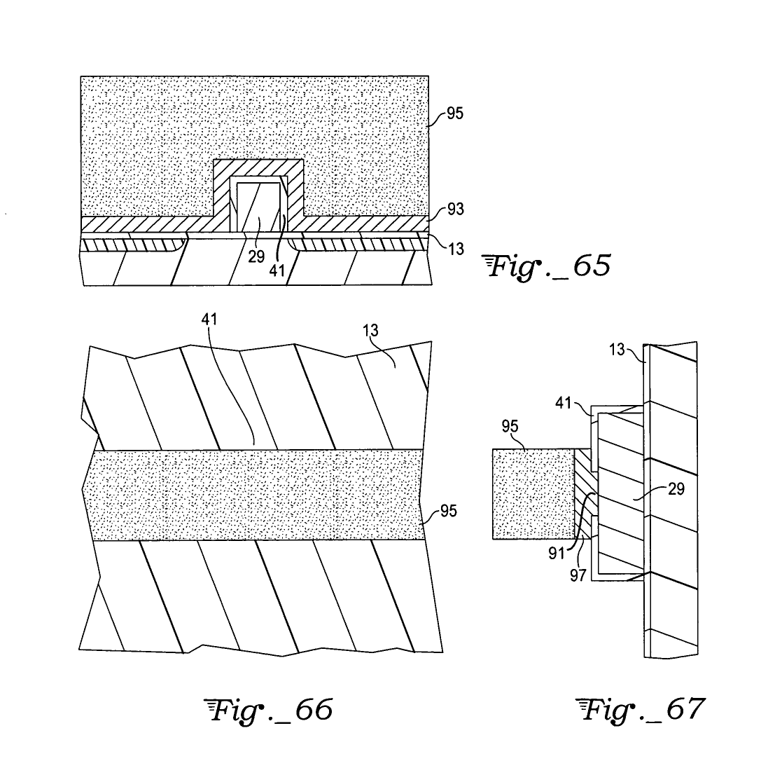

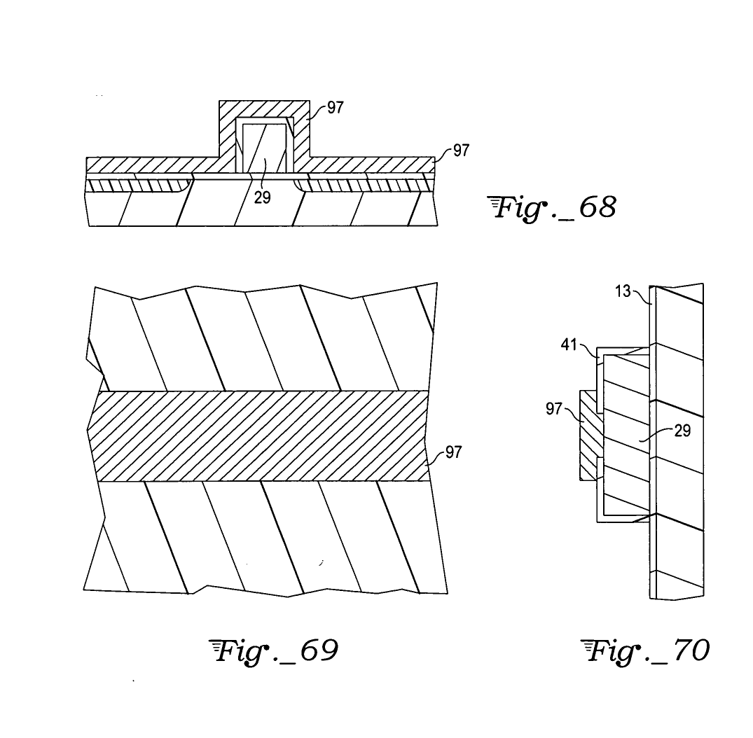

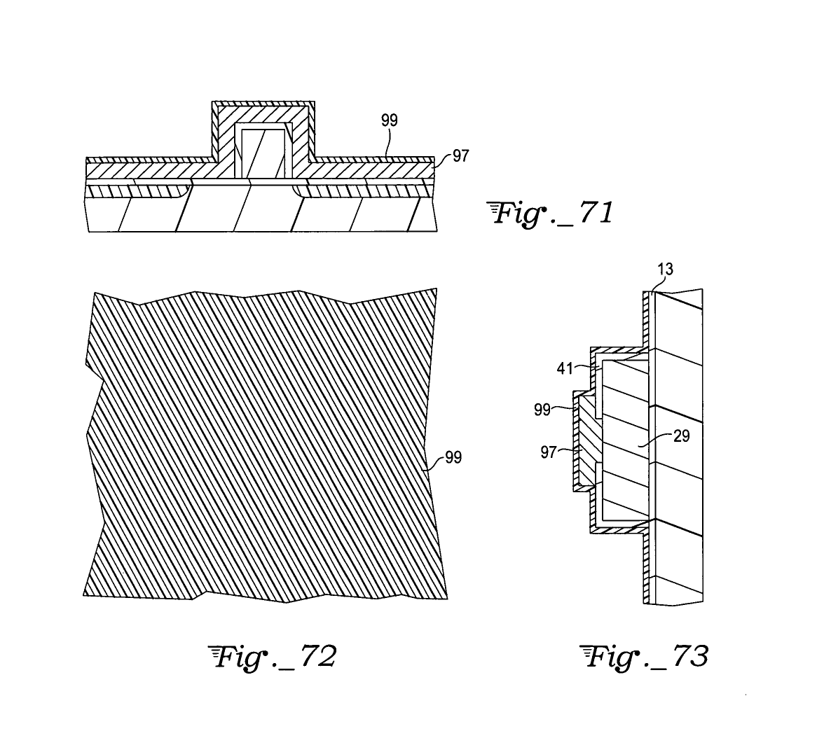

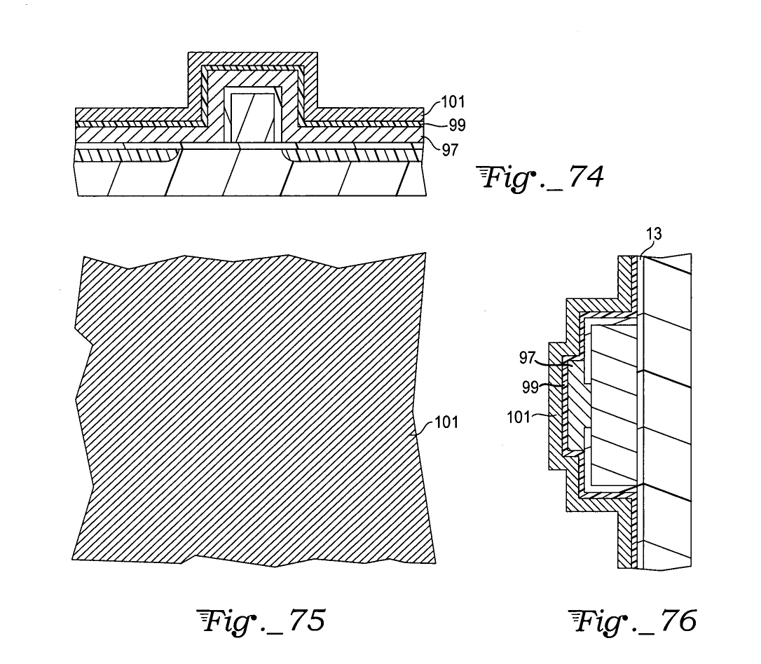

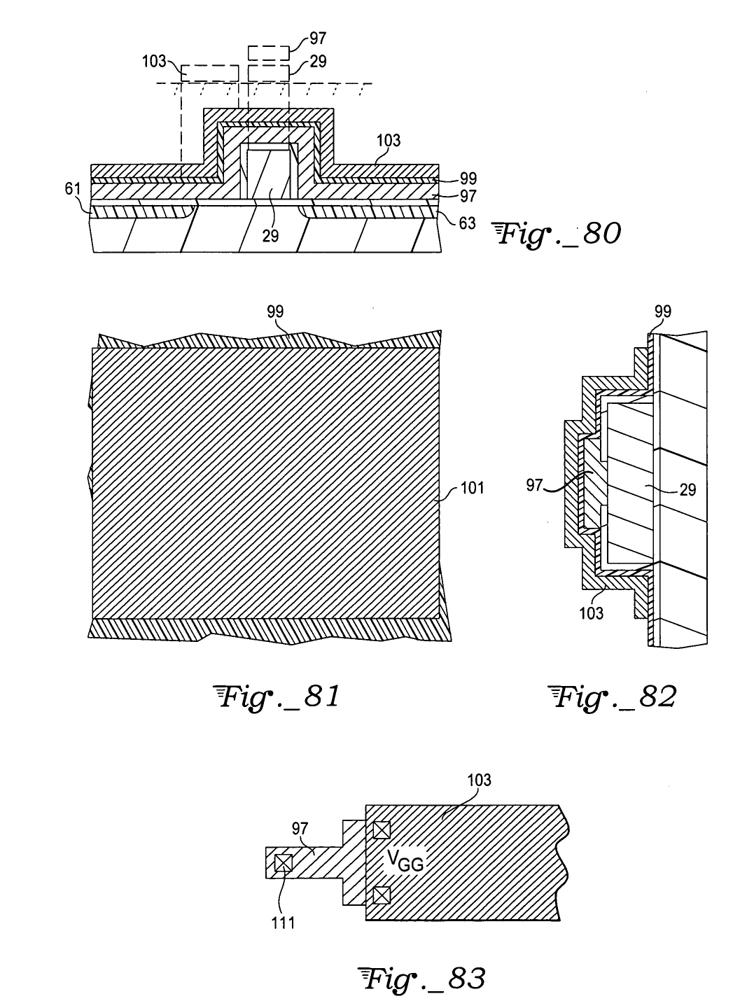

FIGS. 59-61 shows deposition of a second polysilicon layer 93 that will form an erase gate. The layer 93 is seen to completely cover fin block 29 including oxide layers 13 and 41. In FIGS. 62-64 a mask stripe 95 is seen to cover a portion of the second polysilicon layer 93. It must be remembered that the mask stripe 95 not only covers a portion of fin block 29 but extends over all fin blocks in the same row of an X-Y memory array. The purpose of the mask stripe 95 is to trim the second polysilicon layer 93 in all regions except under mask stripe 95, leaving an erase gate stripe 97, seen in FIG. 67. FIGS. 65-67 show removal of most of the second polysilicon layer 93 except under the mask stripe 95 that extends over the tunnel window region 91. FIGS. 68-70 show removal of the mask stripe 95 with the erase gate stripe 97 running from west to east quadrants and over the fin block 29, extending beyond the source and drain electrodes as shown later in FIG. 83.

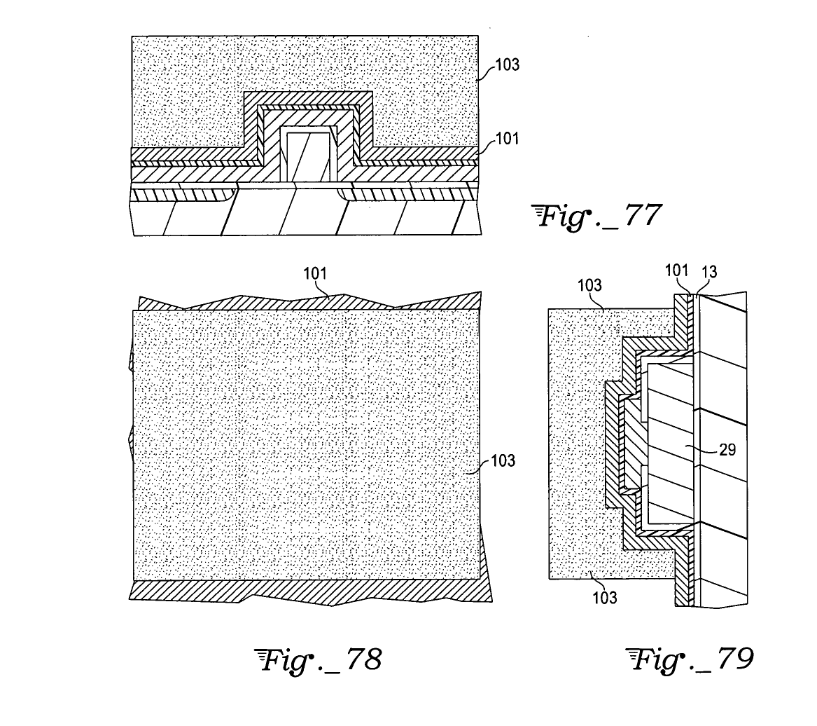

FIGS. 71-73 show deposition of a thin layer 99 of insulator material, namely ONO in a layer about 90 angstroms thick, over the entirety of the wafer. In FIGS. 74-76 a third layer of conductive polysilicon 101 extends completely over the ONO layer 99 which is over the erase gate stripe 97. A wide mask 103 is placed over the third conductive polysilicon layer 101 as seen in FIGS. 77-79. The purpose of the mask is to trim the third layer of conductive polysilicon 101 outwardly of where the third layer steps downwardly over fin block 29 towards oxide layer 13. In this manner the third polysilicon layer 101 will act as a cap over the fin block 29, as well as the erase gate stripe 97 except for a region discussed below.

With the removal of the mask stripe after trimming the third polysilicon layer 101, seen in FIG. 80, the third polysilicon layer 101 is exposed as a polysilicon cap 103 upon removal of mask 95, seen also in FIGS. 81-86. The cap is insulatively spaced by TEOS layer 99 over the second polysilicon stripe 97 which, in turn, is insulatively spaced over fin block 29. FIG. 83 shows that at the east end of a fin block, the erase gate 97 extends out from under cap 103, allowing electrical contact with the erase gate at terminal 111 for application of an erase voltage Vₑᵣₐₛₑ in an insulated manner from the third polysilicon layer 101 formed as a cap except for this contact port. The cap 103 has contacts 112 for application of control gate voltage, V_{CG}. FIGS. 80-82 show the completed fin blocks with conductive overlayers, i.e. supersurface electrodes, that are arranged in rows that are closely spaced in an X-Y array over the surface of a wafer. In FIG. 80 the relative spatial positions of floating gate 29, erase gate 97 and control gate 103 are shown as they exist in a composite sectional view, considering FIGS. 80 and 82 together in relevant detail.

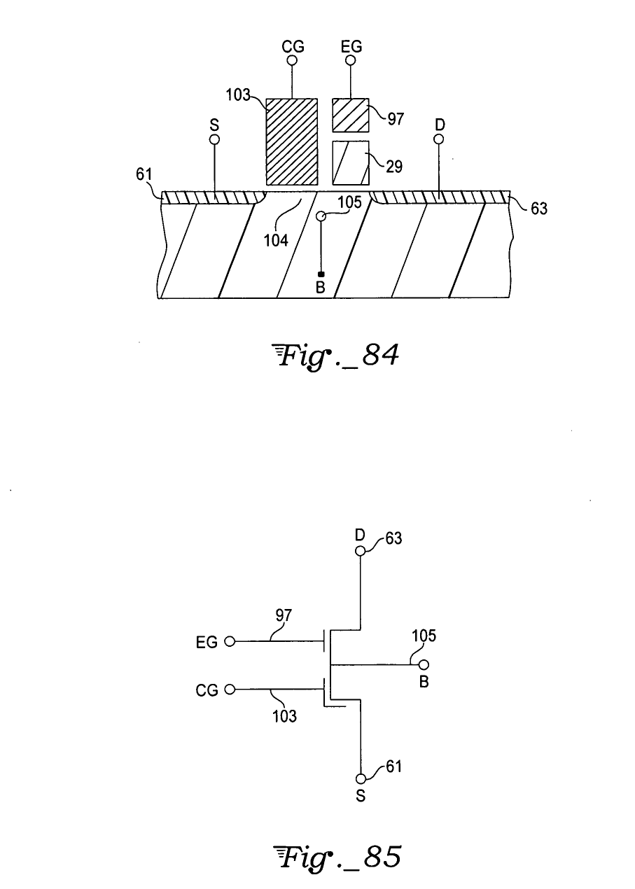

With reference to FIG. 84 the multiple electrodes of the fin block of FIG. 82 are schematically shown as electrodes for a hybrid transistor device. The floating gate 29 is seen to be proximate to drain 63, having an electrical contact, D. Directly above the floating gate 29 is the erase gate 97 having the electrical contact, EG. The spacing of source 61, having electrical contact S, from drain 63, having electrical contact D, allows the cap or control gate layer 103, having electrical contact CG to control and sense charge carrier flow in the channel, together with floating gate 29 between source 61 and drain 63. The erase gate 97 establishes charge carrier flow into and out of floating gate 29. The control gate 103, like floating gate 29, resides above channel region 104, and can help change and monitor the threshold for conduction. The floating gate and control gate together establish the threshold for conduction. In this manner, two transistors, a control transistor and a floating gate memory transistor are combined into a single structure having the common source 61 and drain 63 as subsurface electrodes. The substrate contact, B, is the bulk contact 105 normally grounded. The same electrodes are shown in FIG. 85 now as an electrical symbol for an EEPROM memory cell to be used in a memory array.

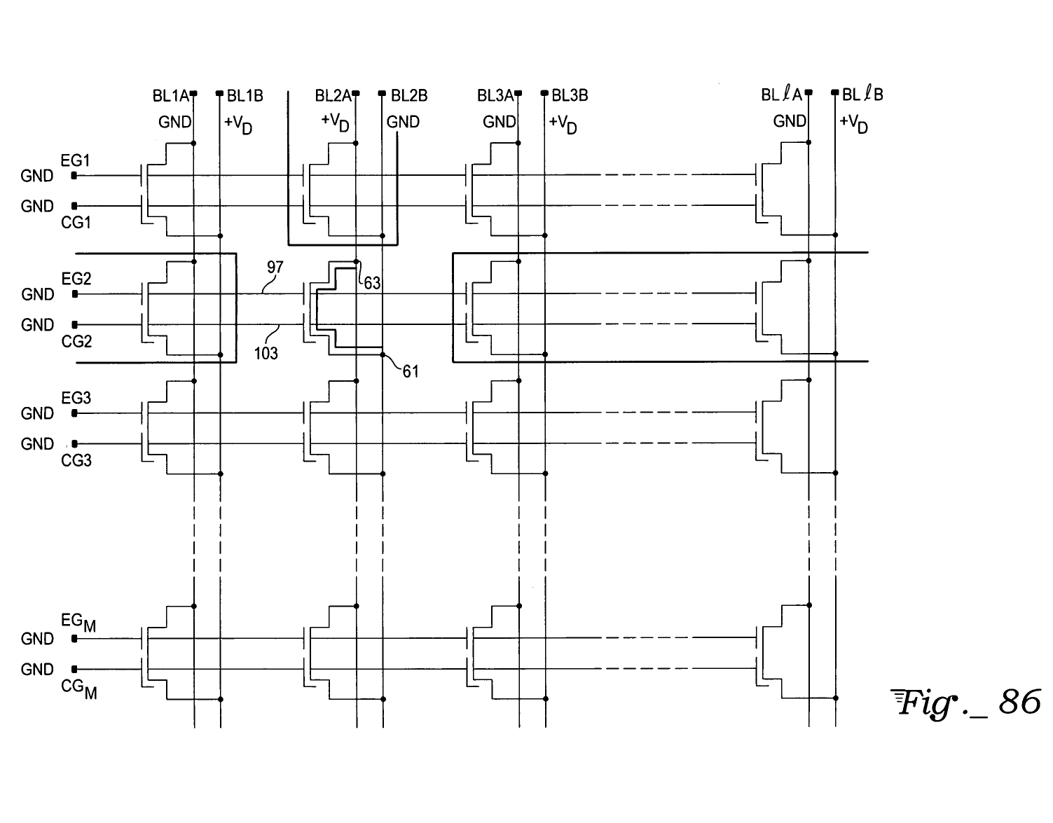

In the X-Y memory array of FIG. 86 memory cells are seen to be aligned in rows and columns. Bit lines, corresponding to subsurface source and drain lines for memory cells, run through each column of the array. Word lines, corresponding to supersurface erase gate and control gate lines run through each row of the array. Each X, Y memory cell location corresponds to a fin block of the type shown in FIGS. 80 and 82. The physical alignment of the fin blocks corresponds to the electrical representation in FIG. 86. Note that source electrodes for all fin blocks in a common column are electrically connected. The same is true for drain electrodes in the same common column. Note that the erase gate electrodes for all fin blocks in a common row are electrically connected. The same is true for control gates for all fin blocks in the same common row.

Assume that it is desired to read a cell at memory position X=2 and Y=2 where the cell X=1 and Y=1 is in the upper left-hand corner of FIG. 86. In the Y vertical direction, each pair of bit lines associated with the memory cells is labeled BLYA and BLYB where BL means bit line, Y is the memory cell column number, A is the drain side bit line and B is the source side bit line. In the X direction each pair of word lines is labeled EGX and CGX where EG means an erase gate line, CG means a control gate line and X is the memory cell row number.

For the selected cell X=2 and Y=2, row 2 and column 2 are selected. Note that the erase gate electrode 97 is part of the word line EG2 and the control gate electrode 103 is part of the word line CG2. At the same time, the drain electrode 63 is part of the bitline BL2A, while the source electrode 61 is part of the bit line BL2B. The selected word line, EG2 is held at ground, while CG2 is held at voltage +V_{D}. For the selected bitlines, the bit line BL2A is held at voltage +V_{D} while bit line BL2B is held at ground. For all unselected columns, the bit line BLYA is held at ground and BLYB is held at +V_{D} where Y is in an unselected column number. For all unselected rows, the word line EGX is held at ground and CGX is held at ground where X is an unselected row number.

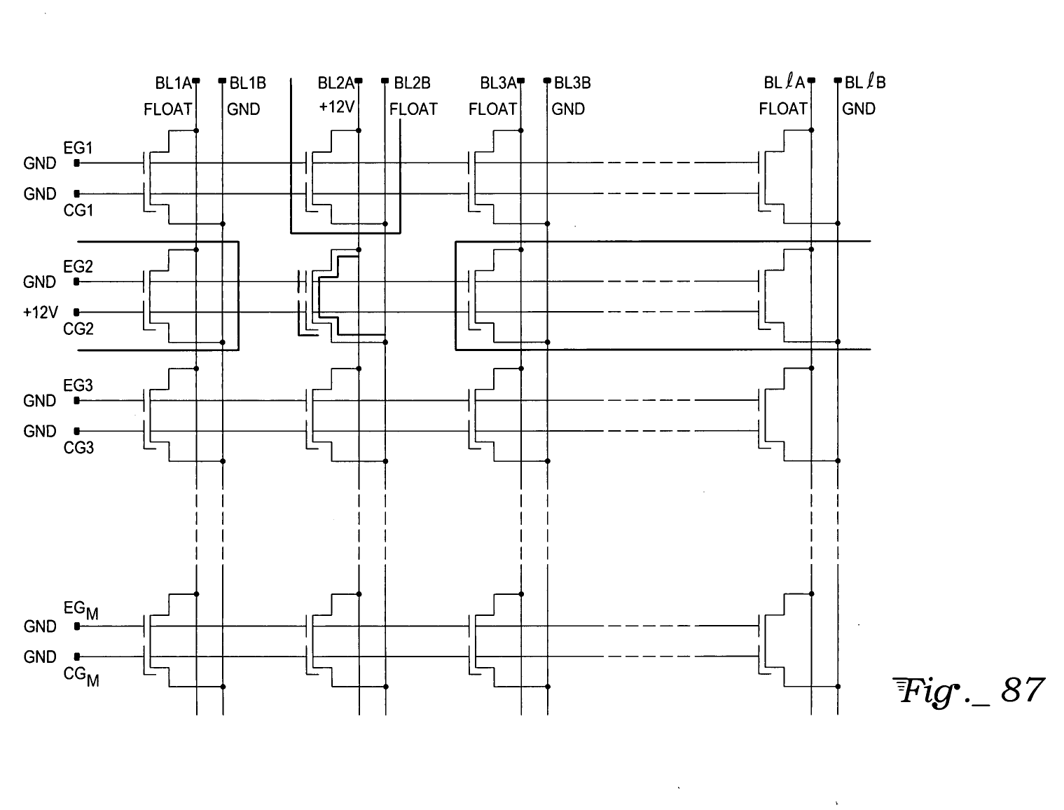

With reference to FIG. 87, assume that it is desired to program the same cell at location X=2 and Y=2. Once again assume that the selected column is 2 and the selected row is 2. In the selected column, the bit line BL2A is held at +12V and the bit line BL2B is held floating. In the selected row, the word line EG2 is held at ground and the word line CG2 is held at +12V. For all unselected columns, the bit line BLYA is held floating and BLYB is held at ground where Y is in an unselected column number. For all unselected rows, the word line EGX is held at ground and CGX is held at ground where X is an unselected row number.

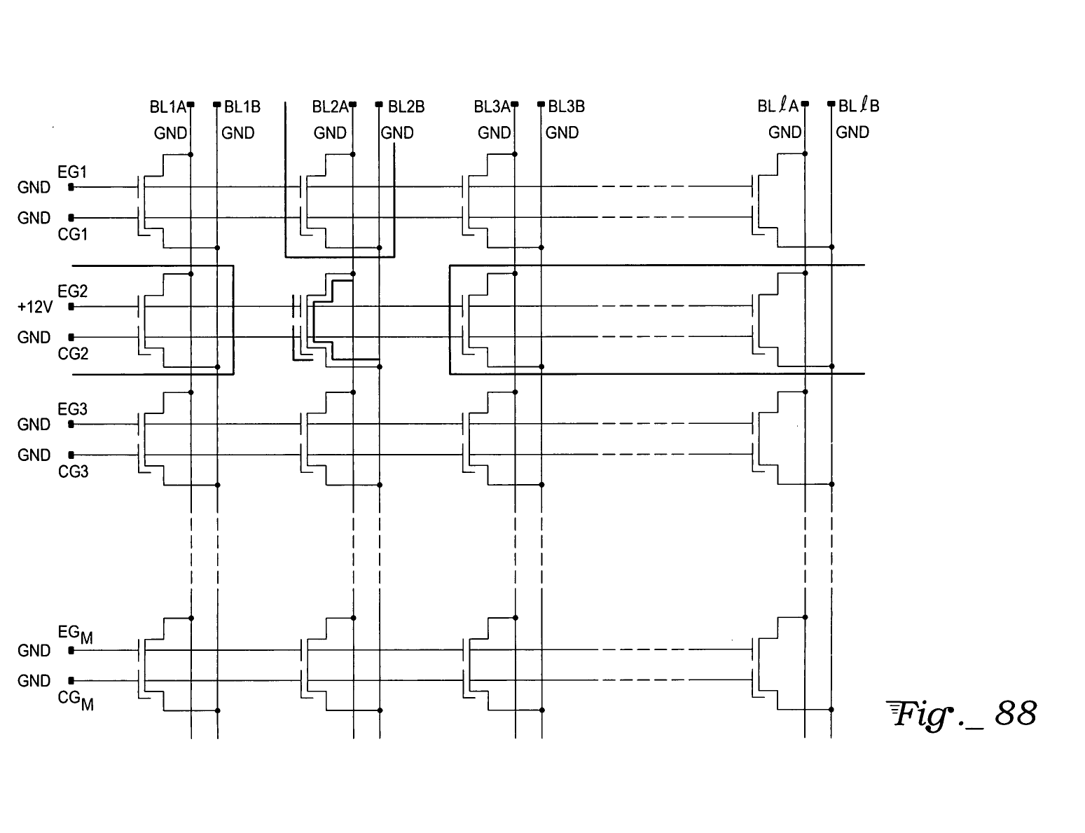

With reference to FIG. 88, assume that it is desired to erase the same cell at location X=2 and Y=2. The selected column is 2 and the selected row is 2. In the selected column, the bit line BL2A is held at ground and the bit line BL2B is held at ground. In the selected row, the word line EG2 is held at +12V and the word line CG2 is held at ground. For all unselected columns, the bit line BLYA is held at ground and BLYB is held at ground where Y is in an unselected column number. For all unselected rows, the word line EGX is held at ground and CGX is held at ground where X is an unselected row number.

While this example of a memory array is an application of fin block wafer scale construction, it is readily apparent that fin blocks can be wired as logic gates. In turn, logic gates can be wired as diverse circuits, including microprocessors. All of this is done with stepperless fabrication.

1. A method of manufacturing semiconductor integrated circuits comprising,
building a plurality of conductive silicon fins on an insulated surface of a semiconductor substrate, the fins aligned in an X-Y array,
making MOS transistors from the fins, the transistors having subsurface and supersurface electrodes in the X-Y array,
connecting selected electrodes in the X-Y array to make an integrated circuit.

2. The method of claim 1 where the transistors are incorporated into blocks with other circuit elements therein, the blocks aligned in rows situated in the X-Y array in a comb-like manner.

3. The method of claim 1 wherein the transistors are nonvolatile memory devices.

4. The method of claim 3 wherein the MOS devices are floating gate transistors.

5. The method of claim 2 wherein each block comprises a floating gate memory cell.

6. The method of claim 5 wherein each memory cell comprises a select gate transistor having at least one electrode shared with a floating gate transistor.

7. The method of claim 1 further defined by making subsurface transistor source and drain electrodes as common wiring lines connecting a plurality of transistors below the insulated surface of the semiconductor substrate.

8. The method of claim 1 further defined by making subsurface transistor gate electrodes as common wiring lines connecting a plurality of transistors above the fins.

9. The method of claim 1 further defined by making common subsurface wiring lines in a first direction connecting a plurality of transistors below the insulated surface of the semiconductor substrate and making common supersurface wiring lines in a second direction connecting a plurality of transistors whereby at least one wiring line in the first direction and at least one wiring line in the second direction communicates with each transistor in said plurality of transistors, where the first and second directions are transverse directions in a plane.

10. The method of claim 7 further defined by arranging the source and drain electrodes as bit lines in a memory array.

11. The method of claim 2 wherein each of said blocks incorporates a memory transistor and a select transistor.

12. The method of claim 11 wherein the memory transistor has a floating gate laterally adjacent to a control gate.

13. A non-volatile memory array comprising,
a plurality of fin blocks arranged in a row on a semiconductor substrate with a plurality of parallel rows and parallel columns defining an X-Y array, each fin block being a non-volatile memory cell,
a plurality of parallel subsurface bitlines, with one pair of bitlines electrically communicating with all fin blocks in a row, and
a plurality of parallel supersurface word lines, with one pair of word lines communicating with all fin blocks in a column.

14. The memory array of claim 13 wherein each memory cell is an EEPROM transistor with a floating gate transistor and a select transistor incorporated into each fin block.

15. The memory array of claim 13 wherein each memory cell is a flash transistor with a floating gate transistor incorporated into each fin block.

16. The memory array of claim 13 wherein each non-volatile memory cell has a floating gate transistor with a floating gate electrode and a thin insulative tunnel window located distal to the semiconductor substrate.

17. The memory cell of claim 16 wherein an erase gate electrode is separated from the floating gate by the tunnel window.

18. The memory cell of claim 17 wherein a control gate is separated from the erase gate by insulative material and caps the erase gate.

19. The memory cell of claim 18 wherein the erase gate and the floating gate are both between a single source and drain.

20. The memory cell of claim 14 wherein the floating gate and select transistors employ the subsurface bitlines as source and drain electrodes.

21. The memory cell of claim 13 wherein each memory cell communicates with two bitlines and two word lines.

22. The memory array of claim 16 wherein said semiconductor substrate is a silicon wafer having an insulative layer beneath a polysilicon layer, the polysilicon layer patterned to form floating gate electrodes.

23. A non-volatile memory array formed by a plurality of fin blocks forming memory cells, each memory cell comprising,
a first polysilicon floating gate fin insulatively disposed over a semiconductor substrate between subsurface source and drain electrodes with a channel therebetween, the floating gate electrode having an insulative layer surrounding the floating gate and incorporating a tunnel window therein, the tunnel window disposed vertically distal to the substrate,
a second polysilicon non-floating gate disposed over the floating gate fin in charge transfer communication with the tunnel window and having an insulative layer surrounding said first polysilicon floating gate, and
a third polysilicon non-floating gate capping the first polysilicon gate and the second polysilicon gate.

24. The memory array of claim 23 wherein at least one of the source and drain electrodes are extended to form bit lines in the array.

25. The memory array of claim 23 wherein at least one of the second and third polysilicon gates is extended to form word lines in the array.

26. The memory array of claim 23 wherein the third polysilicon gate extends toward the substrate at least partially between the source and drain electrodes whereby the second polysilicon gate electrically communicates with the channel between the source and drain electrodes.

27. The memory array of claim 26 wherein said memory cell comprises an EEPROM memory cell including a floating gate transistor and a select transistor.

28. The memory array of claim 23 wherein each memory cell is in a row and column of the memory array, the array having transverse bitlines and word lines communicating with each cell.

29. The memory array of claim 28 wherein the bitlines are integral with subsurface source and drain electrodes.

30. The memory array of claim 28 wherein the word lines are integral with the second and third polysilicon non-floating gates.

31. A floating gate MOS non-volatile memory transistor comprising,
a semiconductor substrate with a major surface with source and drain regions below the surface defining a current carrying channel region therebetween having a first insulative layer over the surface,
a conductive first polysilicon layer on the insulative layer configured as a floating gate over the channel region,
a tunnel window above the floating gate layer surrounded by a thicker second insulative layer,
a conductive second polysilicon layer disposed on the second insulative layer and in charge transfer relation with the first polysilicon layer through the tunnel window,
a third insulative layer above the second polysilicon layer, and
a conductive third polysilicon layer over the third insulative layer and capping the second polysilicon layer and the first polysilicon layer.

32. The transistor of claim 31 wherein the floating gate configuration is a polysilicon fin.
